(19) United States
(12) Patent Application Publication
(10) Pub. No.: US 2015/0047417 A1
(43) Pub. Date: Feb. 19, 2015

(54) CORE-SHELL NANOPARTICLE, METHOD OF FABRICATING THE SAME AND GAS SENSOR USING THE SAME

(71) Applicants: Electronics and Telecommunications Research Institute, Daejeon (KR); Pusan National University Industry-University Cooperation Foundation, Busan (KR)

(72) Inventors: Hyung Ju PARK, Suwon-si (KR); Nak Jin CHOI, Daejeon (KR); Moon Youn JUNG, Daejeon (KR); Dae Sik LEE, Daejeon (KR); Hyuntae KANG, Busan (KR); Kang Hyun PARK, Busan (KR)

(73) Assignees: Electronics and Telecommunications Research Institute, Daejeon (KR); Pusan National University Industry-University Cooperation Foundation, Busan (KR)

(21) Appl. No.: 14/297,984

(22) Filed: Jun. 6, 2014

(30) Foreign Application Priority Data
Aug. 13, 2013 (KR) 10-2013-0096015

(51) Int. Cl. C23C 30/00; G01N 27/30; H01L 21/02

(52) U.S. Cl. CPC C23C 30/00; H01L 21/02565; G01N 27/30
USPC 73/31.06; 427/215; 428/403; 428/404; 438/104

(57) ABSTRACT

The present invention relates to a core-shell nanoparticle, a method of fabricating the same and a gas sensor using the same, more particularly to a core-shell nanoparticle which includes a core including a first metal oxide and a shell including a second metal oxide, the first metal oxide and the second metal oxide being oxides of the same metal having different oxidation states, a method of fabricating the same and a gas sensor using the same.

### CROSS-REFERENCE TO RELATED APPLICATION

This application claims the priority benefit of Korean Patent Application No. 10-2013-0096015, filed on Aug. 13, 2013, in the Korean Intellectual Property Office, the disclosure of which is incorporated herein by reference.

### BACKGROUND

1. Field of the Invention

The present invention relates to a core-shell nanoparticle to stably analyze various compounds, a method of fabricating the same, and a gas sensor using the same.

2. Description of the Related Art

A gas sensor to measure existence of a gas and concentration thereof is applied to various fields, such as not only environment health but military purposes, food and medical appliances. In particular, the gas sensor needs a high-sensitivity sensor detecting material quickly reacting to a particular gas so as to quickly detect a trace amount of gas. Currently, metal oxides are widely used as a sensing material. A change in resistance of the sensing material occurs due to gas absorbed to the surface of the metal oxides, and the sensor measures existence of gas and concentration thereof using the change in resistance. Thus, researches for adjusting sizes, compositions and shapes of sensing materials are being conducted so as to enhance the sensitivity of the sensor.

For example, studies of preparing nanoparticles to remarkably increase the specific surface area of a device, manufacturing a porous material enabling gases to smoothly transfer on the surface of metal oxides or manufacturing a hybrid structure by mixing various catalytic materials.

Methods acquired from such studies may enhance the sensitivity of the sensor but increase resulting structural instability of the sensing material. Particularly, most metal oxides used as the sensing material of the gas sensor are made of transition metals, which involve structural changes when exposed in the air for a long time. Thus, due to these changes, acquired electric signals may be instable or characteristics of the device may not be maintained uniformly over a long time even in a sensing material having high sensitivity. Further, since a metal oxide gas sensor conducts measurement at a comparatively high temperature, structural stability of a sensing material is required so as to use the gas sensor for a long time.

### SUMMARY

An aspect of the present invention provides a core-shell nanoparticle to improve structural stability and to exhibit excellent sensitivity to various compounds, a method of fabricating the same, and a gas sensor using the same.

However, technical problems the present invention aims at solving are not limited to the aforementioned, but those skilled in the art would clearly understood other technical solutions unstated herein from descriptions as follows.

According to an aspect of the present invention, there is provided a core-shell nanoparticle including a core comprising a first metal oxide, and a shell comprising a second metal oxide, the first metal oxide and the second metal oxide being oxides of the same metal having different oxidation states.

The first metal oxide may have a lower oxidation state than the second metal oxide. The first metal oxide and the second metal oxide may be a metal oxide semiconductor.

The metal oxide semiconductor may include an oxide of metal including at least one selected from the group consisting of Sn, Sr, Mg, Ca, Ti, La, Y, Nd, Zr, Fe, V, Al, Zn, In, Ni, Mo, Fe, W, Co, Cn, Ag, Cd, Au, Pd, Pt, Ir, Ru, Cr, Bi and Cu, without being limited thereto.

The core-shell nanoparticle may include at least one selected from the group consisting of Cu₂O@CuO, CoO@Co₂O₃, NiO@Ni₂O₃, FeO@Fe₂O₃, ZnO@ZnO₂, WO₂@WO₃, MoO₂@MoO₃, Ti₂O@Ti₂O₃ and VO₂@ V₂O₅, without being limited thereto.

The shell may have a thickness of 0.1 nm to 20 nm, and the core may have a diameter of 1 nm to 1,000 nm. The core-shell nanoparticle may have at least one shape selected from the group consisting of a spherical shape, an oval shape, a tetrahedral shape, a pentahedral shape, a hexahedral shape, an octahedral shape, a dodecahedral shape and an icosahedral shape, without being limited thereto.

According to an aspect of the present invention, there is provided a method of fabricating a core-shell nanoparticle, the method including preparing a first mixture by mixing a first metal oxide precursor and a first organic solvent, preparing a first metal oxide by heating the first mixture, and fabricating a surface of the first metal oxide into a layer including a second metal oxide by heat-treating the first metal oxide.

The first metal oxide may form a core, and the second metal oxide may form a shell. The first metal oxide may have a lower oxidation state than the second metal oxide and be an oxide of the same metal as for the second metal oxide.

The first mixture may further include at least one polymer selected from the group consisting of polyvinylpyrrolidone (PVP), polystyrene, poly (vinyl acetate) and polyisobutylene.

The fabricating into the layer including the second metal oxide may change the surface of the first metal oxide into the layer including the second metal oxide by heating the first metal oxide at 50° C. to 1,000° C.

The first organic solvent may include at least one selected from the group consisting of aliphatic hydrocarbon solvents, aromatic hydrocarbon solvents, alcohols, ketone solvents, ester solvents, amide solvents and nitrile solvents.

According to an aspect of the present invention, there is provided a gas sensor. The gas sensor may include a substrate, a metal electrode formed on the substrate, and a sensing material layer including at least one of the core-shell nanoparticle formed on the metal electrode.

The sensing material layer may further include at least one catalyst selected from the group consisting of Cu, Pd, Ag, Pt, Ni and Au, without being limited thereto.

The substrate may include at least one substrate selected from the group consisting of an oxide substrate, an alumina (Al₂O₃) substrate, an insulating layer-deposited silicon (Si) substrate and a silicon dioxide (SiO₂) substrate, without being limited thereto.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 illustrates a schematic structure of a core-shell nanoparticle according to an exemplary embodiment of the present invention;

FIG. 2 illustrates a gas sensor including the core-shell nanoparticle according to an exemplary embodiment of the present invention;

FIG. 3 illustrates multi-linear electrode sensor units according to an exemplary embodiment of the present invention;

FIG. 4 is an electron micrograph of the core-shell nanoparticle according to the exemplary embodiment;

FIG. 5 is an optical micrograph of the core-shell nanoparticle according the exemplary embodiment; and

FIG. 6 is an HCHO graph illustrating gas responses of the gas sensor including the core-shell nanoparticle according to an exemplary embodiment of the present invention.

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the accompanying drawings, however, the present invention is not limited thereto or restricted thereby.

When it is determined a detailed description related to a related known function or configuration that may make the purpose of the present invention unnecessarily ambiguous in describing the present invention, the detailed description will be omitted here. Also, terms used herein are defined to appropriately describe the exemplary embodiments of the present invention and thus may be changed depending on a user, the intent of an operator, or a custom. Accordingly, the terms must be defined based on the following overall description of this specification.

The present invention discloses a core-shell nanoparticle, in which oxides of the same metal having different oxygen proportions form a core and a shell. The core-shell nanoparticle with such a configuration may reduce structural instability of an oxide due to exposure to heat and air over a long period of time. Further, when the core-shell nanoparticle is applied to a gas sensor using a metal oxide as a sensing material, structural deformation of the gas sensor due to high-temperature operating environments and long-time exposure to the air may be prevented, thereby uniformly maintaining performance of the gas sensor over a long period of time.

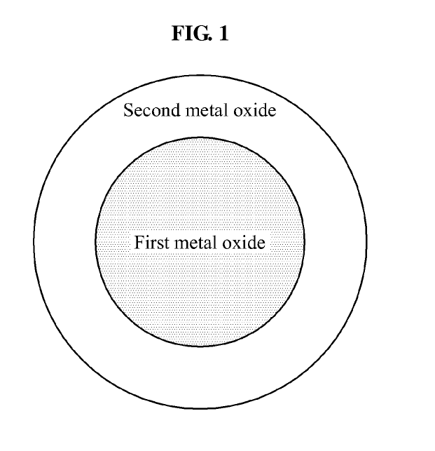

FIG. 1 illustrates a schematic structure of a core-shell nanoparticle according to an exemplary embodiment of the present invention. Referring to FIG. 1, the core-shell nanoparticle may include a core including a first metal oxide and a shell including a second metal oxide. The first metal oxide and the second metal oxide may be oxides of the same metal having different oxygen proportions. For example, the first metal oxide and the second metal oxide are oxides of the same metal, and the first metal oxide has a lower proportion of oxygen than the second metal oxide. Since the core including the first metal oxide is surrounded by the shell including the second metal oxide having a higher proportion of oxygen, the first metal oxide may maintain structural stability for a long time. Moreover, when the core-shell nanoparticle is applied to a sensing material for a gas sensor, the gas sensor may not only provide excellent sensitivity but also enhance stability.

In one exemplary embodiment, the oxygen proportions of the metal oxides may be represented as an oxidation state, in which case the first metal oxide may have a lower oxidation state than the second metal oxide.

The first metal oxide and the second metal oxide is metal oxides applicable as a sensing material of a gas sensor, preferably a metal oxide semiconductor, and more preferably a metal oxide semiconductor including a transition metal.

The metal oxide semiconductor may be a metal oxide including at least one selected from the group consisting of Sn, Sr, Mg, Ca, Ti, La, Y, Nd, Zr, Fe, V, Al, Zn, In, Ni, Mo, Fe, W, Co, Cn, Ag, Cd, Au, Pd, Pt, Ir, Ru, Cr, Bi and Cu. For example, the metal oxide semiconductor may be at least one selected from the group consisting of SnO₂, ZnO, ZnO₂, MnO₂, MoO₃, COO, Co₂O₃, MgO, NiO, WO₃, WO₂, Co₃O₄, Fe₂O₃, FeO, TiO₂, Ti₂O₃, VO₂, V₂O₅, BaTiO₃, In₂O₃, ZrO₂, CuAlO₂, Bi₂O₃, WO₃, Ni₂O₃, NiO, SnO, CUO, Cu₂O, CaO, La₂O₃, Nd₂O₃, Y₂O₃, CeO₂, PbO, ZrO₂, V₂O₅, Nb₂O₅, Ti doped SnO₂, Sn doped ZnO, Mg doped ZnO, Mn doped ZnO, Ni doped ZnO, Co doped ZnO, Fe doped ZnO, Mn doped MgO, Ni doped MgO, Co doped MgO, Fe doped MgO, Mg doped MnO₂, Ni doped MnO₂, Co doped MnO₂, Fe doped MnO₂, Mg doped NiO, Mn doped NiO, Co doped NiO, Fe doped NiO, Mg doped Co₃O₄, Mn doped Co₃O₄, Ni doped Co₃O₄, Fe doped Co₃O₄, Mg doped Fe₂O₃, Mn doped Fe₂O₃, Ni doped Fe₂O₃, Co doped Fe₂O₃ and Ag doped ZnO, without being limited thereto.

Preferably, the core-shell nanoparticle includes at least one selected from the group consisting of Cu₂O@CuO, CoO@Co₂O₃, NiO@Ni₂O₃, FeO@Fe₂O₃, ZnO@ZnO₂, WO₂@WO₃, MoO₂@MoO₃ and Ti₂O@Ti₂O₃, without being limited thereto.

In the core-shell nanoparticle, the shell has a thickness of 0.1 nm to 20 nm, and the core has a diameter of 1 nm to 1,000 nm. Preferably, the thickness of the shell is smaller than the diameter of the core.

The core-shell nanoparticle may have any shape as long as the core-shell nanoparticle is applicable to the gas sensor. The core-shell nanoparticle preferably has at least one shape selected from the group consisting of a spherical shape, an oval shape, a tetrahedral shape, a pentahedral shape, a hexahedral shape, an octahedral shape, a dodecahedral shape and an icosahedral shape, without being limited thereto.

The present invention provides a method of fabricating the core-shell nanoparticle. The method may include preparing a first mixture, preparing a first metal oxide, and forming a second metal oxide layer.

Preparation of First Mixture

In preparing the first mixture, the first mixture is prepared by mixing a first metal oxide precursor and a first organic solvent. A metal of the first metal oxide precursor forms the core of the core-shell nanoparticle, and examples thereof have been illustrated as above. The first metal oxide precursor may be at least one selected from the group consisting of metal alkoxide, a sulfate, a nitrate, an acetate, a chloride, a phosphate, a carbonate, a hydroxide and an oxalate, without being limited thereto.

The first mixture may further include a polymer compound, which may be at least one selected from the group consisting of polyvinylpyrrolidone (PVP), polystyrene, poly(vinyl acetate) and polyisobutylene, without being limited thereto. The polymer compound may be heated at 150° C. to 250° C. and then added to the first mixture.

The first organic solvent may include at least one selected from the group consisting of aliphatic hydrocarbon solvents, aromatic hydrocarbon solvents, alcohols, ketone solvents, glycols, ester solvents, acetate solvents, amide solvents and nitrile solvents and be mixed with water. Specifically, the first organic solvent may be n-pentane, i-pentane, n-hexane, i-hexane, 2,2,4-trimethylpentane, cyclohexane, benzene, toluene, xylene, trimethylbenzene, ethylbenzene, methyl alcohol, ethyl alcohol, n-propanol, i-propanol, n-butanol, i-butanol, sec-butanol, t-butanol, 4-methyl-2-pentanol, cyclohexanol, methylcyclohexanol, acetone, methyl ethyl ketone, methyl-n-propyl ketone, methyl-n-butyl ketone, methyl-i-butyl ketone, diethyl ketone, cyclohexanone, methylcyclohexanone, acetylacetone, tetrahydrofuran, 2-methyltetrahydrofuran, ethylene glycol, diethylene glycol, triethylene glycol, propylene glycol, butylene glycol, hexylene glycol, 1,3-propanediol, 1,4-butanediol, 1,2,4-butanetriol, 1,5-pentanediol, 1,2-hexanediol, 1,6-hexanediol, ethyl ether, n-propyl ether, i-propyl ether, n-butyl ether, diglyme, dioxin, dimethyl dioxin, ethylene glycol monomethyl ether, ethylene glycol monoethyl ether, ethylene glycol-n-propyl ether, ethylene glycol dimethyl ether, ethylene glycol diethyl ether, propylene glycol monomethyl ether, propylene glycol monoethyl ether, propylene glycol monopropyl ether, propylene glycol dimethyl ether, propylene glycol diethyl ether, propylene glycol dipropyl ether, diethyl carbonate, methyl acetate, ethyl acetate, n-propyl acetate, i-propyl acetate, n-butyl acetate, ethyl actate, ethylene glycol monomethyl ether acetate, ethylene glycol monoethyl ether acetate, propylene glycol monomethyl ether acetate, propylene glycol monomethyl ether acetate, propylene glycol monopropyl ether acetate, ethylene glycol diacetate, propylene glycol diacetate, N-methylpyrrolidone, formamide, N-methylformamide, N-ethylformamide, N,N-dimethylformamide, N,N-diethylformamide, N-methylacetamide, N-ethylacetamide, N,N-dimethylacetamide and N,N-diethylacetamide, without being limited thereto.

The first mixture may further include a surfactant, which may be at least one selected from the group consisting of a cation surfactant, an anion surfactant, a nonionic surfactant and an amphiprotic surfactant. Specifically, the surfactant may be cetyltrimethylammonium chloride, lauryl dimethylbenzyl ammonium chloride, 2-hydroxycetyl-2-hydroxy dimethyl ammonium chloride, lauryl trimethyl ammonium chloride, behenyl trimethyl ammonium chloride, polyoxyethylenated n-nonylphenol, p-octylphenol, p-dodecylphenol, polyoxyethylenated polyoxypropylene glycol, polyoxyethylenated mercaptan, polyoxyethylenated straight-chain alcohol, glyceryl of natural fatty acids, polyglyceryl ester, and polyoxyethylenated sorbitan ester, without being limited thereto.

Preparation of First Metal Oxide

In preparing the first metal oxide, the first metal oxide is prepared by heating the first mixture. The first mixture is heated at temperature in which the first metal oxide is formed, for example, 100° C. to 500° C., preferably 150° C. to 400° C. for 1 to 10 hours.

Formation of Second Metal Oxide Layer

In forming the second metal oxide layer, the second metal oxide layer is formed on a surface of the first metal oxide. The second metal oxide layer forms the shell of the core-shell nanostructure, and examples thereof have been illustrated as above. Specifically, the second metal oxide layer is formed on the surface of the first metal oxide by heating the first metal oxide, in which the surface of the first metal oxide is oxidized by heating to form a second metal oxide having a different oxidation state from the first metal oxide. The heating is carried out at temperature that causes oxidation of the first metal oxide, for example, 50° C. to 1,000° C., preferably 80° C. to 600° C., and more preferably 80° C. to 300° C. for 10 minutes to 10 hours.

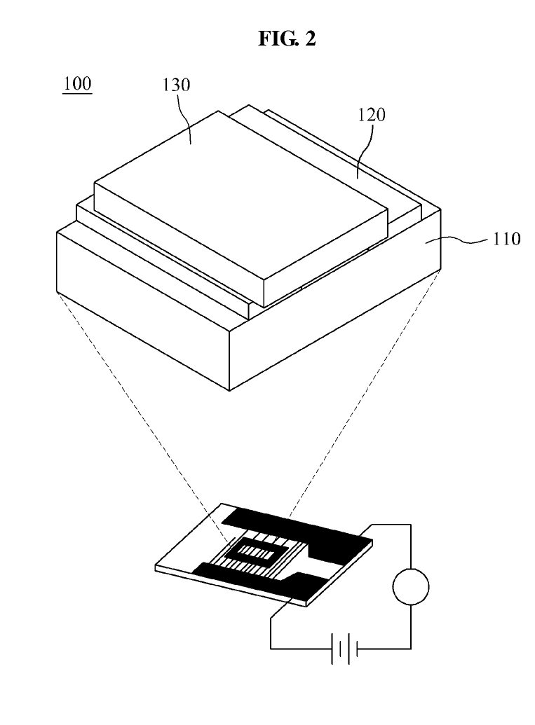

The present invention provides a gas sensor including the core-shell nanoparticle. FIG. 2 illustrates the gas sensor including the core-shell nanoparticle according to an exemplary embodiment of the present invention. The gas sensor is described in detail with reference to FIG. 2. The gas sensor 100 may include a heater (not shown), a substrate 110 on the heater, an electrode 120 formed on the substrate 110 and a sensing material 130 formed on the electrode 120.

The heater may include any heater that is applicable to the gas sensor. The substrate 110 may include any substrate that is applicable to the gas sensor, for example, at least one selected from the group consisting of an oxide substrate, an alumina (Al₂O₃) substrate, an insulating layer-deposited silicon (Si) substrate and a silicon dioxide (SiO₂) substrate, without being limited thereto.

The electrode 120 may include any electrode that is applicable to the gas sensor, for example, a metal electrode including at least one selected from the group consisting of Pt, Pd, Ag, Au, Ni, Ti, Cr, Al, Cu, Sn, Mo, Ru and In, without being limited thereto. In the present embodiment, the electrode may be a multi-linear electrode.

The sensing material 130 includes the core-shell nanoparticle and may further include a catalyst applicable to the gas sensor in order to enhance sensitivity of the gas sensor. Specifically, the catalyst may be at least one catalyst selected from the group consisting of CU, Pd, Ag, Pt, Ni and Au, without being limited thereto.

Further, the sensing material 130 may further include a metal oxide applicable to the gas sensor in addition to the core-shell nanoparticle, wherein the metal oxide is preferably a metal oxide semiconductor and examples thereof have been illustrated as above.

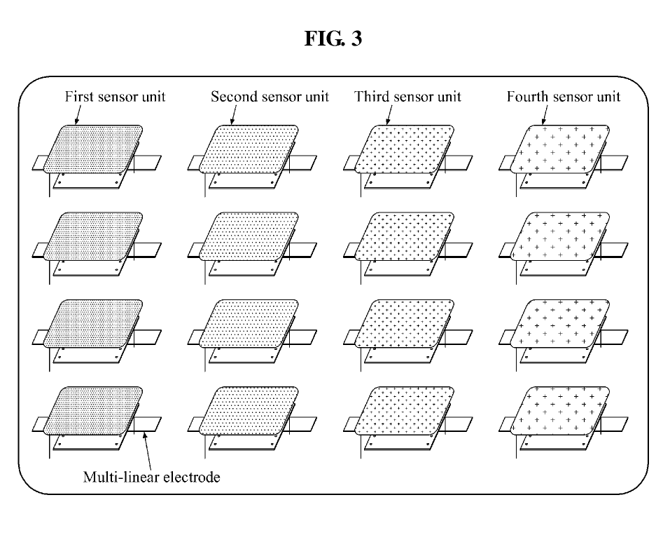

FIG. 3 illustrates multi-linear electrode sensor units according to an exemplary embodiment of the present invention. Referring to FIG. 3, the gas sensor may be integrated with the multi-linear sensor units arraying a plurality of sensing materials. First to fourth sensor units form the foregoing structure of the gas sensor. The first to fourth sensor units are formed of the same or different sensing material layers. The sensor units may be configured by fixing the sensing materials onto the multi-linear electrodes mounted on the heater to detect a change in resistance due to gas absorption between electrodes or on the entire surface of the electrodes.

The gas sensor may be manufacture by any method generally known in the art, which is not particularly limited.

Although exemplary embodiments of the present invention have been shown and described, it would be appreciated by those skilled in the art that changes may be made to these exemplary embodiments without departing from the principles and spirit of the invention, the scope of which is defined by the claims and their equivalents.

### Example 1

### Gas Sensor Using Cu₂O@CuO Nanocube

(1) Preparation of Cu₂O@CuO Nanocube

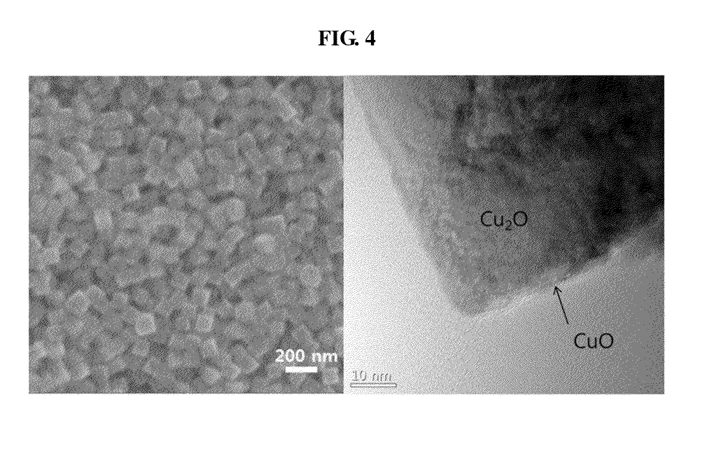

5.3 g of polyvinylpyrrolidone (PVP) was melted in a 45-ml solution of 1,5-pentadiol at 240° C., and 4 mmol of Cu(CO₂CH₃)₂ was melted in 15 ml of 1,5-pentadiol. The copper precursor solution was put in the PVP solution and reacted for 10 minutes while stirring at 240° C., thereby obtaining Cu₂O nanocubes. When the Cu₂O nanocubes were heated in the air at 80° C. for about two hours, a surface of Cu₂O nanocubes was oxidized, thereby forming Cu₂O@ CuO nanocubes. The obtained Cu₂O@ CuO nanocubes were examined with a transmission microscope, and examination results are illustrated in FIG. 4.

(2) Manufacture of Gas Sensor

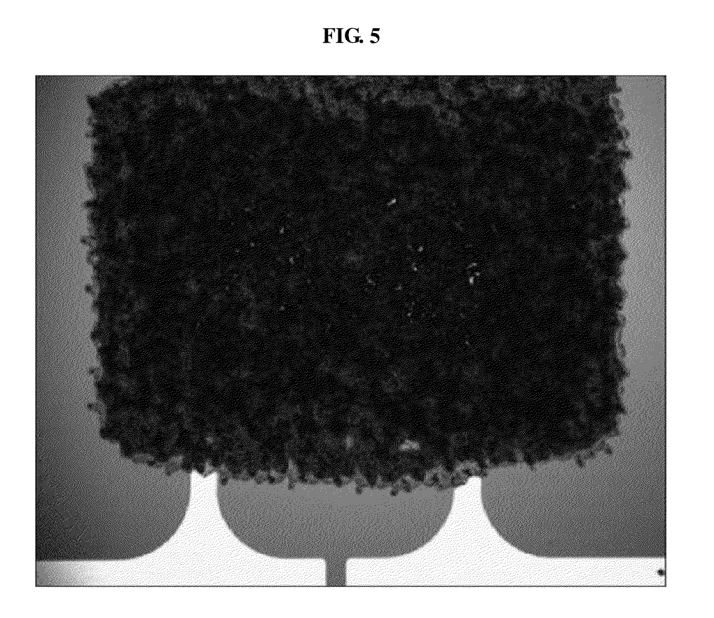

Paste of the prepared nanocubes was printed on a multi-linear electrode having a gap between electrodes of 5 μm, the electrodes being made of a 0.675 mm-thick silicone substrate and having a thickness of 100 nm and a width of 10 μm, thereby manufacturing a gas sensor. The sensing material layer of the manufacture gas sensor is shown in FIG. 5.

Evaluation of Characteristics of HCHO Gas Reaction of Gas Sensor

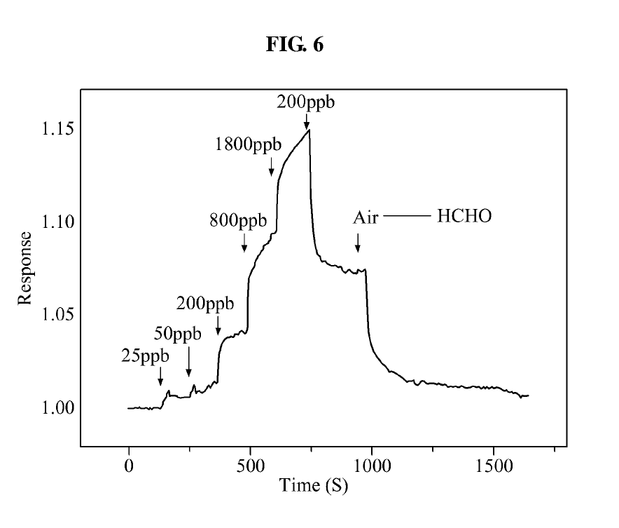

A measuring system for the gas sensor includes a thermostat to adjust operating temperature of the sensor to 50° C. to 1,000° C. and a plurality of mass flow controllers (MFCs) installed to adjust HCHO gas concentration to 1 ppb to 500 ppm. The measuring system investigated a change in resistance of the gas sensor according to a concentration change while changing the temperature from room temperature to 700° C. and adjusting the HCHO gas concentration to 5 ppb to 300 ppm. Investigation results are illustrated in FIG. 6.

Measurement sensitivity is acquired as a ratio of resistance of the gas sensor in a particular material to resistance of the gas sensor measured in the air by the following equation.

S=R_{gas}/Rₐᵢᵣ

S: Measurement sensitivity

R_{gas}: Resistance of gas sensor measured in particular material

Rₐᵢᵣ: Resistance of gas sensor measured in the air

FIG. 6 is a graph illustrating different HCHO concentrations and gas responses in use of the gas sensor manufactured in Example 1. Referring to FIG. 6, when the sensing material is heated to 300° C. in the gas sensor according to Example 1, a small change in HCHO concentration of about 25 to 1,800 ppb is identified based on a resistance change in the multi-linear electrode. Although the resistance change is not relatively substantial, high stability of the sensing material enables a change in electrical characteristics of low-concentration HCHO to be clearly observed.

According to exemplary embodiments of the present invention, the aforementioned purposes of the present invention may be achieved. Specifically, a core-shell nanoparticle according to the present invention may provide a core-shell metal oxide nanoparticle with enhanced structural stability by changing oxygen proportions of metal oxides each forming a core and a shell.

Also, when applied to a gas sensor, the core-shell nanoparticle may prevent deterioration in stability of the gas sensor caused by high gas measuring temperature and long-time exposure to the air, thereby enhancing measuring efficiency of the sensor.

In addition, when used as a sensing material of the gas sensor, the core-shell nanoparticle may provide the gas sensor having less electrical signal noise and clearly distinguishing a low-concentration gas reaction.

The gas sensor according to the present invention is integrated into various types of gas sensors to analyze presence or absence of various kinds of gases and concentrations thereof and to be utilized not only for environment health but for military purposes, food and medical appliances.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

1. A core-shell nanoparticle, comprising:
a core comprising a first metal oxide; and
a shell comprising a second metal oxide,
the first metal oxide and the second metal oxide being oxides of the same metal having different oxidation states.

2. The core-shell nanoparticle of claim 1, wherein the first metal oxide has a lower oxidation state than the second metal oxide.

3. The core-shell nanoparticle of claim 1, wherein the first metal oxide and the second metal oxide are a metal oxide semiconductor.

4. The core-shell nanoparticle of claim 3, wherein the metal oxide semiconductor comprises an oxide of metal comprising at least one selected from the group consisting of Sn, Sr, Mg, Ca, Ti, La, Y, Nd, Zr, Fe, V, Al, Zn, In, Ni, Mo, Fe, W, Co, Cn, Ag, Cd, Au, Pd, Pt, Ir, Ru, Cr, Bi and Cu.

5. The core-shell nanoparticle of claim 1, wherein the core-shell nanoparticle comprises at least one selected from the group consisting of Cu₂O@CuO, CoO@Co₂O₃, NiO@Ni₂O₃, ZnO@ZnO₂, WO₂@WO₃, MoO₂@MoO₃, Ti₂O@Ti₂O₃ and VO₂@V₂O₅.

6. The core-shell nanoparticle of claim 1, wherein the shell has a thickness of 0.1 nm to 20 nm, and the core has a diameter of 1 nm to 1,000 nm.

7. The core-shell nanoparticle of claim 1, wherein the core-shell nanoparticle has at least one shape selected from the group consisting of a spherical shape, an oval shape, a tetrahedral shape, a pentahedral shape, a hexahedral shape, an octahedral shape, a dodecahedral shape and an icosahedral shape.

8. A method of fabricating a core-shell nanoparticle, the method comprising:
preparing a first mixture mixing a first metal oxide precursor and a first organic solvent;
preparing a first metal oxide by heating the first mixture; and
fabricating a surface of the first metal oxide into a layer comprising a second metal oxide by heat-treating the first metal oxide.

9. The method of claim 8, wherein the first metal oxide forms a core, and the second metal oxide forms a shell.

10. The method of claim 8, wherein the first metal oxide has a lower oxidation state than the second metal oxide and is an oxide of the same metal as for the second metal oxide.

11. The method of claim 8, wherein the first metal oxide and the second metal oxide are a metal oxide semiconductor, and the metal oxide semiconductor comprises a metal oxide comprising at least one selected from the group consisting of Sn, Sr, Mg, Ca, Ti, La, Y, Nd, Zr, Fe, V, Al, Zn, In, Ni, Mo, Fe, W, Co Cn, Ag, Cd, Au, Pd, Pt, Ir, Ru, Cr, Bi and Cu.

12. The method of claim 8, wherein the first mixture further comprises at least one polymer selected from the group consisting of polyvinylpyrrolidone (PVP), polystyrene, poly(vinyl acetate) and polyisobutylene.

13. The method of claim 8, wherein the fabricating into the layer comprising the second metal oxide changes the surface of the first metal oxide into the layer comprising the second metal oxide by heating the first metal oxide at 50° C. to 1,000° C.

14. The method of claim 8, wherein the first organic solvent comprises at least one selected from the group consisting of aliphatic hydrocarbon solvents, aromatic hydrocarbon solvents, alcohols, ketone solvents, ester solvents, amide solvents and nitrile solvents.

15. A gas sensor, comprising:
a substrate;
a metal electrode formed on the substrate; and
a sensing material layer comprising at least one of the core-shell nanoparticle of claim 1 formed on the metal electrode.

16. The gas sensor of claim 15, wherein the sensing material layer further comprises at least one catalyst selected from the group consisting of Cu, Pd, Ag, Pt, Ni and Au.

17. The gas sensor of claim 15, wherein the substrate comprises at least one substrate selected from the group consisting of an oxide substrate, an alumina (Al₂O₃) substrate, an insulating layer-deposited silicon (Si) substrate and a silicon dioxide (SiO₂) substrate.

18. A gas sensor, comprising:
a substrate;
a metal electrode formed on the substrate; and
a sensing material layer comprising at least one of the core-shell nanoparticle of claim 2 formed on the metal electrode.

19. A gas sensor, comprising:
a substrate;
a metal electrode formed on the substrate; and
a sensing material layer comprising at least one of the core-shell nanoparticle of claim 3 formed on the metal electrode.

20. A gas sensor, comprising:
a substrate;
a metal electrode formed on the substrate; and
a sensing material layer comprising at least one of the core-shell nanoparticle of claim 4 formed on the metal electrode.
